(19) United States
(12) Patent Application Publication
(10) Pub. No.: US 2017/0033098 A1
(43) Pub. Date: Feb. 2, 2017

(54) GaN-BASED SCHOTTKY DIODE RECTIFIER

(71) Applicant: INSTITUTE OF SEMICONDUCTORS, CHINESE ACADEMY OF SCINCES, Beijing (CN)

(72) Inventors: Zhi HE, Beijing (CN); Junxi WANG, Beijing (CN); Wei YAN, Beijing (CN); Jinxia GUO, Beijing (CN); Xiaoyan YI, Beijing (CN); Zhongchao FAN, Beijing (CN)

(21) Appl. No.: 15/039,701

(22) PCT Filed: Nov. 26, 2013
(86) PCT No.: PCT/CN2013/087837

§ 371 Date: May 26, 2016

(51) Int. Cl. H01L 27/06; H01L 29/205; H01L 29/40; H01L 21/02; H01L 29/66; H01L 29/20; H01L 29/872

(52) U.S. Cl. CPC H01L 27/0605; H01L 29/2003; H01L 29/205; H01L 29/872; H01L 21/0254; H01L 29/66143; H01L 29/401

(57) ABSTRACT

The present disclosure involves a GaN-based Schottky diode rectifier and a method of manufacturing the same. The GaN-based Schottky diode rectifier includes: a substrate, on which a GaN intrinsic layer and a barrier layer are grown in turn; a p-type two-dimension electron gas depletion layer located on an upper surface of the barrier layer; a cathode electrode located at a position on the upper surface of the barrier layer where is different from the position where the p-type two-dimension electron gas depletion layer is formed; and an anode electrode including a first part and a second part electrically connected to each other.

### CROSS-REFERENCE TO RELATED APPLICATIONS

This application is a U.S. National Stage Application of International Application No. PCT/CN2013/087837, filed Nov. 26, 2013, entitled “GaN-Based Schottky Diode Rectifier”, which is incorporated herein by reference in its entirety.

### FEDERALLY SPONSORED RESEARCH OR DEVELOPMENT

Not Applicable.

### TECHNICAL FIELD

The present invention relates to technology field of manufacturing semiconductor devices, and particularly to a GaNS chottky diode rectifier with a p-GaN layer added onto an AlGaN/GaN junction and a method of manufacturing the same.

### BACKGROUND

GaN material is particularly suitable to be used as a material for manufacturing a high-voltage, high-temperature, high-power and high-density integrated electronic device due to its characteristics such as large forbidden band width, high critical breakdown voltage and high thermal conductivity, etc.

GaN material may be used to form a heterojunction structure with AlGaN or InAlN, etc. Due to spontaneous polarization effect and piezoelectric polarization effect of a barrier material, such as AlGaN or InAlN, a two-dimension electron gas (2DEG) with high concentration and high mobility may be generated at the interface of the heterojunction. This characteristic may not only improve carrier mobility and working frequency of a GaN-based device, but also reduce conduction resistance and switching delay thereof. As GaN material may be epitaxially grown on a silicon substrate, producing cost of a device may be largely reduced.

Due to its high breakdown voltage and rapid switching speed, a GaN-based Schottky diode rectifier may be widely used in electric and electronic fields of, such as, electrical source management, wind power generation, solar energy cell, electric vehicle or the like. By comparing with traditional Schottky diode rectifier, a GaN-based Schottky diode rectifier may have a more rapid switching speed and may undertake higher reverse voltage, and thus will have a considerable application in devices, whose reverse voltage is within a range of 600V˜1200V. However, the current GaN-based Schottky diode rectifier still has the following shortcomings:

1. Its reverse leakage current is rather large. Due to its small potential barrier, the reverse leakage current of the current Schottky diode rectifier is much bigger than that of a PN-junction diode, which renders the GaN-based Schottky diode rectifier have a reduced breakdown voltage.

2. Its positive turn-on voltage is non-adjustable. The conventional Schottky diode rectifier has a constant turn-on voltage that is generally fixed to 0.7V and cannot be adjusted, due to limitation of Schottky potential barrier.

3. It is not a heterojunction structure. Thus, no two-dimension electron gas is involved, which results in large conduction resistance, slow switching speed and high power consumption.

4. Its surge resistant ability is rather low as there is no other way providing for conduction current under conditions of huge electrical current.

For the above shortcomings, a common approach is provided to perform a p-type doping in GaN material at both sides of and under an anode of the Schottky diode rectifier and an n-type doping in GaN material at both sides of and under a cathode of the same. The p-type doped region and the n-type doped region may form a reverse-biased PN junction, suppressing the leakage current of the device. In a situation where the positive current is abruptly increased, the PN junction is caused to be turned on and thus holes are injected. Hole current may play a role of shuntting with respect to total current, which thus avoids burning-out of the device.

However, the above approach does not involve a heterojunction structure and thus results in a large conduction resistance. In addition, the positive turn-on voltage of the device is non-adjustable. Thus, there is problem of how to reduce leakage current of a GaN-based Schottky diode, increase its breakdown voltage and reduce its conduction resistance.

### SUMMARY

Embodiments of the present disclosure provide a new structure of a GaN-based Schottky diode rectifier mainly characterized by a p-GaN layer or p-AlGaN layer added on the basis of an Al(In)GaN/GaN structure. An anode of the Schottky diode is formed on the added p-GaN layer or p-AlGaN barrier layer, so that they have equal electrical potential. A cathode is formed on the AlGaN barrier layer.

Adding the p-GaN layer or p-AlGaN layer may modulate energy band of the AlGaN/GaN structure and lead to depletion of the two-dimension electron gas in a channel of the AlGaN/GaN structure, which thus may turn off the channel. When the device is used, its anode is provided with a positive voltage such that the two-dimension electron gas is recovered and the channel is conducted.

Embodiments of the present disclosure may have the following advantages:

1. By changing the dopant concentration in the p-GaN layer or p-AlGaN layer, the two-dimension electron gas of the device may be recovered under different positive voltages such that the channel may be conducted, enabling adjustment of the positive turn-on voltage V_{f1} of the Schottky diode.

2. The p-GaN layer or p-AlGaN layer and the AlGaN/GaN structure form a PN junction. When the Schottky diode is under a reversely biased condition, the PN junction is also under a reversely biased condition, which may cause reverse leakage current of the Schottky diode to be effectively reduced so as to increase the breakdown voltage of the Schottky diode.

3. The p-GaN layer or p-AlGaN layer and the AlGaN/GaN structure are formed into a PN junction. When the positive current is abruptly increased to exceed beyond the positive turn-on voltage V_{f2} of the PN junction, holes injection will be generated so as to form a hole current which plays a role of shunting with respect to total current, which may avoid burning-out of the device when the total current of the device is abruptly increased.

4. The device involves the AlGaN/GaN heterojunction structure and a two-dimension electron gas, and thus achieves reduced conduction resistance, effectively reduced switching delay and power consumption.

### BRIEF DESCRIPTION OF THE DRAWINGS

In order to more explicitly illustrate the objects, contents and advantages of the present invention, description in detail will be made in combination with the embodiments by referring to the drawings, in which:

FIG. 1 is a schematic view of a GaN-based Schottky diode structure according to a first embodiment.

FIG. 2 is a schematic view of a GaN-based Schottky diode structure according to a second embodiment.

FIG. 3 is a schematic view of a GaN-based Schottky diode structure according to a third embodiment.

FIG. 4 is a schematic view of a GaN-based Schottky diode structure according to a fourth embodiment.

FIG. 5 is a schematic view of a GaN-based Schottky diode structure according to a fifth embodiment.

FIG. 6 is a schematic view of a GaN-based Schottky diode structure according to a sixth embodiment.

FIG. 7 illustrates one step in the process of manufacturing a GaN-based Schottky diode according to a first embodiment.

FIG. 8 illustrates another step in the process of manufacturing a GaN-based Schottky diode according to a first embodiment.

FIG. 9 illustrates another step in the process of manufacturing a GaN-based Schottky diode according to a first embodiment.

FIG. 10 illustrates another step in the process of manufacturing a GaN-based Schottky diode according to a first embodiment.

FIG. 11 illustrates another step in the process of manufacturing a GaN-based Schottky diode according to a first embodiment.

FIG. 12 illustrates another step in the process of manufacturing a GaN-based Schottky diode according to a first embodiment.

FIG. 13 illustrates another step in the process of manufacturing a GaN-based Schottky diode according to a first embodiment.

FIG. 14 illustrates another step in the process of manufacturing a GaN-based Schottky diode according to a first embodiment.

FIG. 15 illustrates another step in the process of manufacturing a GaN-based Schottky diode according to a first embodiment.

FIG. 16 illustrates another step in the process of manufacturing a GaN-based Schottky diode according to a first embodiment.

FIG. 17 illustrates another step in the process of manufacturing a GaN-based Schottky diode according to a first embodiment.

FIG. 18 illustrates one step in the process of manufacturing a GaN-based Schottky diode according to a second embodiment.

FIG. 19 illustrates another step in the process of manufacturing a GaN-based Schottky diode according to a second embodiment.

FIG. 20 illustrates another step in the process of manufacturing a GaN-based Schottky diode according to a second embodiment.

FIG. 21 illustrates another step in the process of manufacturing a GaN-based Schottky diode according to a second embodiment.

FIG. 22 illustrates another step in the process of manufacturing a GaN-based Schottky diode according to a second embodiment.

FIG. 23 illustrates another step in the process of manufacturing a GaN-based Schottky diode according to a second embodiment.

FIG. 24 illustrates another step in the process of manufacturing a GaN-based Schottky diode according to a second embodiment.

FIG. 25 illustrates another step in the process of manufacturing a GaN-based Schottky diode according to a second embodiment.

FIG. 26 illustrates another step in the process of manufacturing a GaN-based Schottky diode according to a second embodiment.

FIG. 27 illustrates another step in the process of manufacturing a GaN-based Schottky diode according to a second embodiment.

FIG. 28 illustrates another step in the process of manufacturing a GaN-based Schottky diode according to a second embodiment.

FIG. 29 illustrates one step in the process of manufacturing a GaN-based Schottky diode according to a third embodiment.

FIG. 30 illustrates another step in the process of manufacturing a GaN-based Schottky diode according to a third embodiment.

FIG. 31 illustrates another step in the process of manufacturing a GaN-based Schottky diode according to a third embodiment.

FIG. 32 illustrates another step in the process of manufacturing a GaN-based Schottky diode according to a third embodiment.

FIG. 33 illustrates another step in the process of manufacturing a GaN-based Schottky diode according to a third embodiment.

FIG. 34 illustrates another step in the process of manufacturing a GaN-based Schottky diode according to a third embodiment.

FIG. 35 illustrates another step in the process of manufacturing a GaN-based Schottky diode according to a third embodiment.

FIG. 36 illustrates another step in the process of manufacturing a GaN-based Schottky diode according to a third embodiment.

FIG. 37 illustrates another step in the process of manufacturing a GaN-based Schottky diode according to a third embodiment.

FIG. 38 illustrates one step in the process of manufacturing a GaN-based Schottky diode according to a fourth embodiment.

FIG. 39 illustrates another step in the process of manufacturing a GaN-based Schottky diode according to a fourth embodiment.

FIG. 40 illustrates another step in the process of manufacturing a GaN-based Schottky diode according to a fourth embodiment.

FIG. 41 illustrates another step in the process of manufacturing a GaN-based Schottky diode according to a fourth embodiment.

FIG. 42 illustrates another step in the process of manufacturing a GaN-based Schottky diode according to a fourth embodiment.

FIG. 43 illustrates another step in the process of manufacturing a GaN-based Schottky diode according to a fourth embodiment.

FIG. 44 illustrates another step in the process of manufacturing a GaN-based Schottky diode according to a fourth embodiment.

FIG. 45 illustrates another step in the process of manufacturing a GaN-based Schottky diode according to a fourth embodiment.

FIG. 46 illustrates another step in the process of manufacturing a GaN-based Schottky diode according to a fourth embodiment.

FIG. 47 illustrates one step in the process of manufacturing a GaN-based Schottky diode according to a fifth embodiment.

FIG. 48 illustrates another step in the process of manufacturing a GaN-based Schottky diode according to a fifth embodiment.

FIG. 49 illustrates another step in the process of manufacturing a GaN-based Schottky diode according to a fifth embodiment.

FIG. 50 illustrates another step in the process of manufacturing a GaN-based Schottky diode according to a fifth embodiment.

FIG. 51 illustrates another step in the process of manufacturing a GaN-based Schottky diode according to a fifth embodiment.

FIG. 52 illustrates another step in the process of manufacturing a GaN-based Schottky diode according to a fifth embodiment.

FIG. 53 illustrates another step in the process of manufacturing a GaN-based Schottky diode according to a fifth embodiment.

FIG. 54 illustrates another step in the process of manufacturing a GaN-based Schottky diode according to a fifth embodiment.

FIG. 55 illustrates another step in the process of manufacturing a GaN-based Schottky diode according to a fifth embodiment.

FIG. 56 illustrates another step in the process of manufacturing a GaN-based Schottky diode according to a fifth embodiment.

FIG. 57 illustrates one step in the process of manufacturing a GaN-based Schottky diode according to a sixth embodiment.

FIG. 58 illustrates another step in the process of manufacturing a GaN-based Schottky diode according to a sixth embodiment.

FIG. 59 illustrates another step in the process of manufacturing a GaN-based Schottky diode according to a sixth embodiment.

FIG. 60 illustrates another step in the process of manufacturing a GaN-based Schottky diode according to a sixth embodiment.

FIG. 61 illustrates another step in the process of manufacturing a GaN-based Schottky diode according to a sixth embodiment.

FIG. 62 illustrates another step in the process of manufacturing a GaN-based Schottky diode according to a sixth embodiment.

FIG. 63 illustrates another step in the process of manufacturing a GaN-based Schottky diode according to a sixth embodiment.

FIG. 64 illustrates another step in the process of manufacturing a GaN-based Schottky diode according to a sixth embodiment.

FIG. 65 illustrates another step in the process of manufacturing a GaN-based Schottky diode according to a sixth embodiment.

FIG. 66 illustrates another step in the process of manufacturing a GaN-based Schottky diode according to a sixth embodiment.

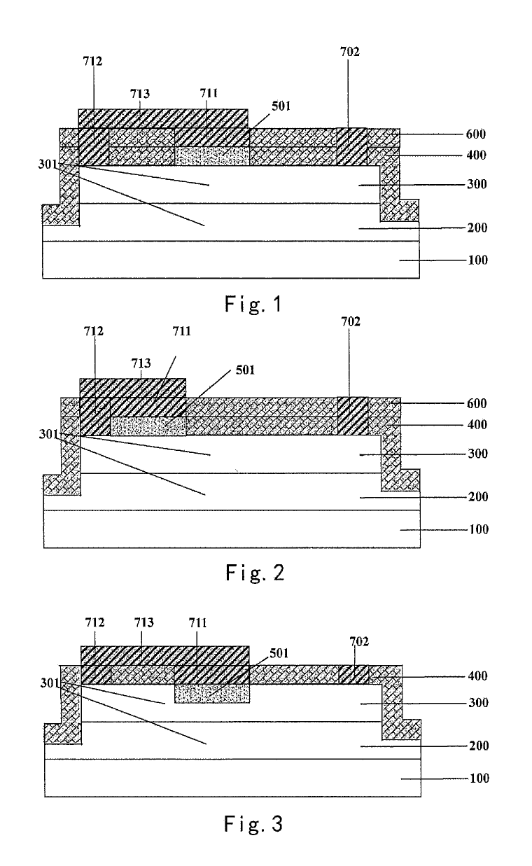

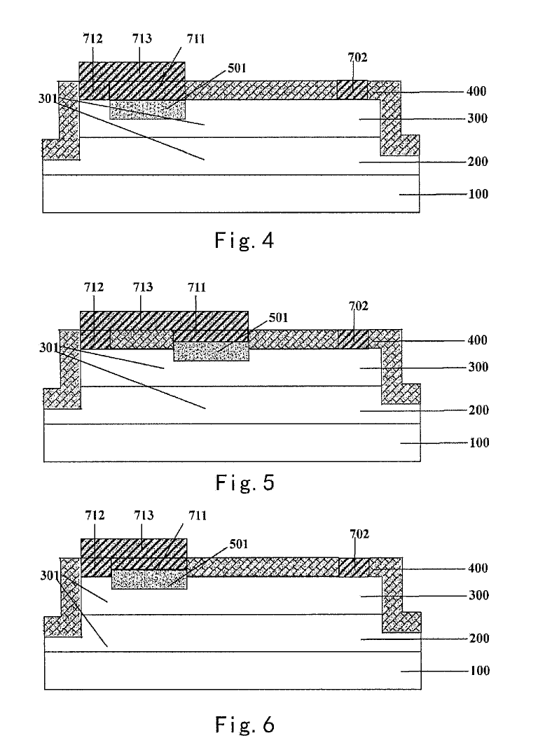

### DETAILED DESCRIPTION OF EMBODIMENTS

In order to make clearer understanding of the above objects, features and advantages of the present disclosure, the present application will be described hereinafter in detail with reference to exemplary embodiments and attached drawings.

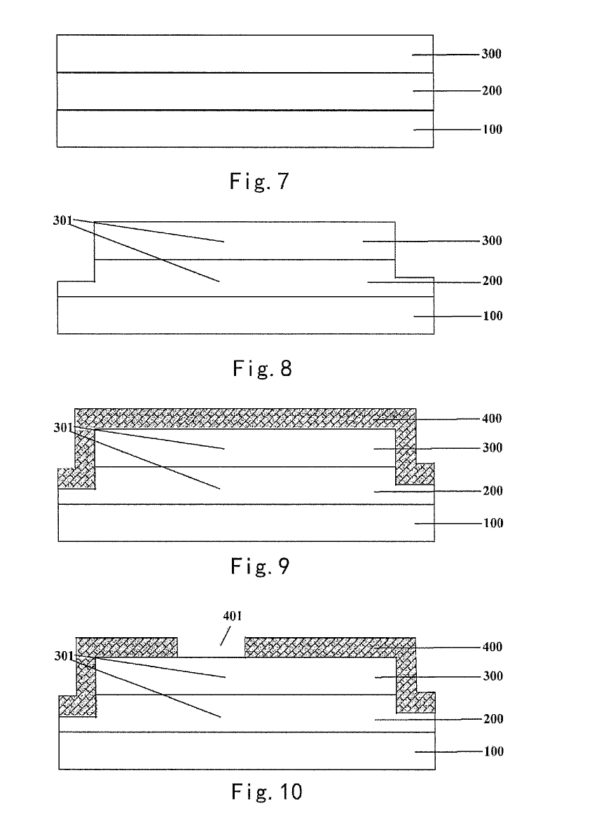

A first embodiment of a method of manufacturing a GaN-based Schottky diode rectifier junction is shown in FIGS. 7-17.

As shown in FIG. 7, a GaN intrinsic layer 200 with a thickness in a range of 50 nm˜10 μm is grown on a substrate 100. An AlGaN barrier layer 300 with a thickness in a range of 20 nm˜1 μm is grown on the GaN intrinsic layer 200. The substrate 100 may be made of GaN, sapphire, Si, diamond or SiC. The barrier layer 300 may be made of AlN, InN, InGaN or InAlN.

As shown in FIG. 8, a protruded mesa pattern 301 is formed from the AlGaN barrier layer 300 and the GaN intrinsic layer 200 by removing unwanted materials from the AlGaN barrier layer 300 and the GaN intrinsic layer 200 by using lithographic technology and plasma dry etching technology. A GaN-based Schottky diode device will be manufactured on the mesa pattern 301, so that one device may be formed on one mesa. Since there is no two-dimension electron gas connecting the mesas, the mesas are electrically insulated or isolated from each other such that a plurality of GaN-based Schottky diode devices on the same wafer are electrically insulated or isolated from each other. The height of the mesa may be larger than or equal to the thickness of the AlGaN barrier layer 300.

As shown in FIG. 9, a first passivated dielectric layer 400 is deposited on the mesa 301 and the passivated dielectric layer 400 may be made of SiO₂, Si₃N₄, AlN, Al₂O₃, MgO, Sc₂O₃, TiO₂, HfO₂, BCB, ZrO₂, Ta₂O₅ or La₂O₃. The first passivated dielectric layer 400 may be deposited by sputtering or chemical vapor deposition (CVD) or epitaxial growth and may have a thickness in a range of 5 nm˜10 μm. Preferably, the passivated dielectric layer 400 may have a thickness of 20 nm.

As shown in FIG. 10, a pattern 401 is formed in the first passivated dielectric layer 400 by lithographic, plasma dry etching or wet etching technology. The pattern 401 may have a depth that is the same as the thickness of the passivated dielectric layer 400.

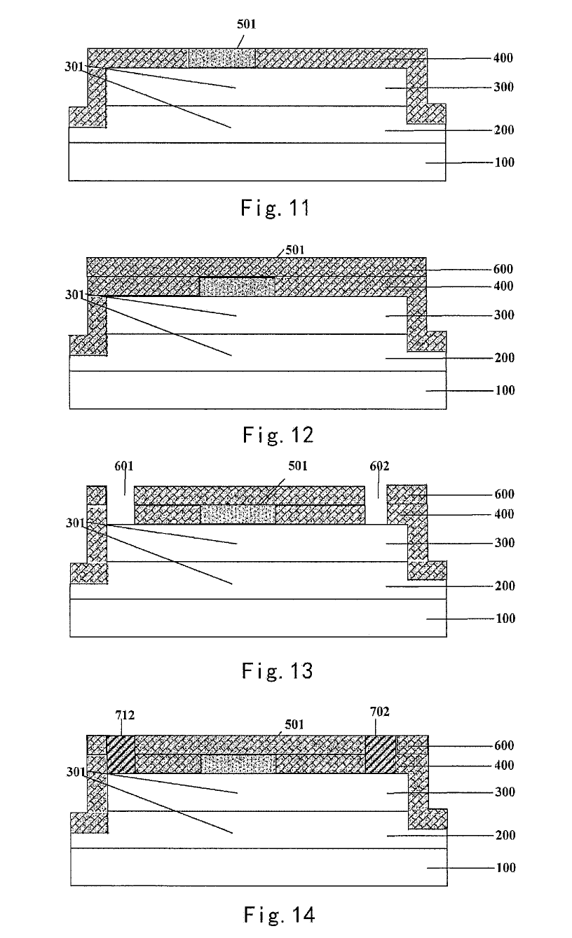

As shown in FIG. 11, a p-GaN layer 501 is selectively grown in the pattern 401, the p-GaN layer 501 may be grown by metal organic chemical vapor deposition (MOCVD), molecular-beam epitaxy (MBE) or atomic layer deposition. The selectively grown p-GaN layer 501 may have a thickness in a range of 20 nm˜1 μm. Preferably, the p-GaN layer 501 may have a thickness of 20 nm. The upper surface of the p-GaN layer 501 does not exceed beyond that of the passivated dielectric layer 400 in a grown direction or epitaxial direction. The p-GaN layer 501 may be made of GaN or AlGaN and may have a dopant concentration in a range of 10¹⁵˜10²¹ cm⁻³, preferably of 10²⁰ cm⁻³. Preferably, by changing the dopant concentration in the p-GaN layer or p-AlGaN layer, the two-dimension electron gas of the device may be recovered under various positive voltages, so that channel of the device is conducted, thereby adjusting positive turn-on voltage Vf₁ of the Schottky diode device. The p-GaN layer or the p-AlGaN layer and the AlGaN/GaN structure form a PN junction. When the GaN-based Schottky diode is under a reversely biased condition, the PC junction is also under a reversely biased condition, which may cause reverse leakage current of the Schottky diode to be effectively reduced so as to increase the breakdown voltage of the Schottky diode. When the positive current is abruptly increased to exceed beyond the positive turn-on voltage V_{f2} of the PN junction, holes injection will be generated to form a hole current which will play a role of shunting with respect to a total current of the device, which may avoid burn-out of the device when the total current is abruptly increased.

As shown in FIG. 12, a second passivated dielectric layer 600 is deposited on the first passivated dielectric layer 400. The second passivated dielectric layer 600 is made of SiO₂, Si₃N₄, AlN, Al₂O₃, MgO, Sc₂O₃, TiO₂, HfO₂, BCB, ZrO₂, Ta₂O₅ or La₂O₃. The second passivated dielectric layer 600 is deposited by sputtering or chemical vapor deposition (CVD) and may have a thickness in a range of 20 nm˜1 μm.

As shown in FIG. 13, patterns 601 and 602 are formed in the first passivated dielectric layer 400 and the second passivated dielectric layer 600 by lithographic, plasma dry etching or wet etching technology. The patterns 601 and 602 are required to have a depth that is the same as a sum of the thickness of the first passivated dielectric layer 400 and the thickness of the second passivated dielectric layer 600.

As shown in FIG. 14, metal electrodes 712 and 702 are respectively formed in the patterns 601 and 602 by lithographic, electron beam evaporation or sputtering technology. The metal electrodes 712 and 702 are respectively located at either side of the p-GaN layer 501 and are not in contact with the p-GaN layer 501. In this instance, the process for forming this structure may be performed easily and may achieve high yield. The metal electrodes 712 and 702 may be made of Ti, Al, Ni, Mo, Pt, Pd, Au, W, TiW, TiN or any of combinations thereof. Ohmic contacts may be obtained between the metal electrodes 712 and 702 and the AlGaN barrier layer 300 by high temperature alloy annealing.

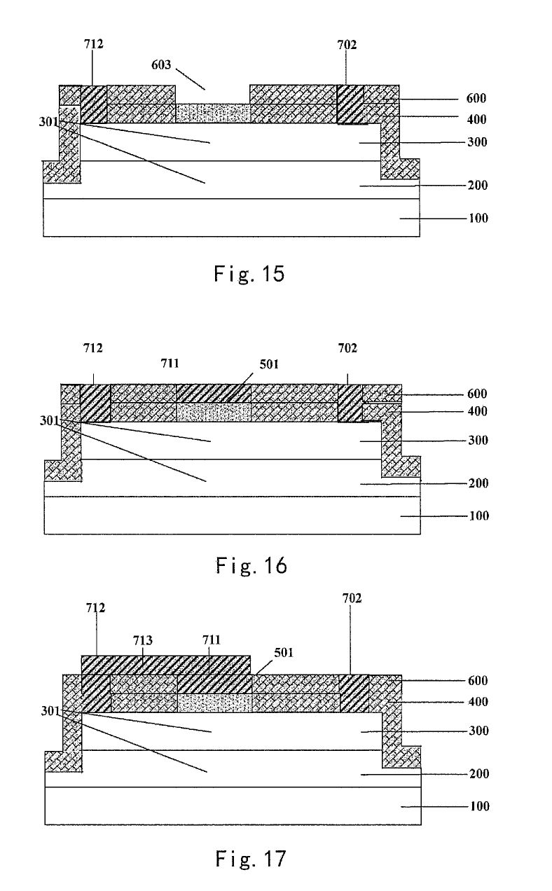

As shown in FIG. 15, pattern 603 is formed in the second passivated dielectric layer 600 by lithographic, plasma dry etching or wet etching technology. The pattern 603 is required to have a depth that is large enough to fully expose the p-GaN layer 501.

As shown in FIG. 16, a metal electrode 711 is formed in the pattern 603 by lithographic, electron beam evaporation or sputtering technology. The metal electrode 711 may be made of Ti, Al, Ni, Mo, Pt, Pd, Au, W, TiW, TiN or any of combinations thereof. Ohmic contact may be formed between the metal electrode 711 and the p-GaN layer 501 by high temperature annealing, or Schottky contact may be formed therebetween, as described in non-patent document 1 (document 1: Uemoto, Y., et al., A normally-off AlGaN/GaN transistor with R(on)A=2.6 m Omega cm(2) and BV(ds)=640V using conductivity modulation. 2006 International Electron Devices Meeting, Vols 1 and 2. 2006, New York: Ieee. 654˜657).

As shown in FIG. 17, a metal electrode 713 is formed on the second passivated dielectric layer 600 by lithographic, electron beam evaporation or sputtering technology. The metal electrode 713 may be made of Ti, Al, Ni, Mo, Pt, Pd, Au, W, TiW, TiN or any of combinations thereof.

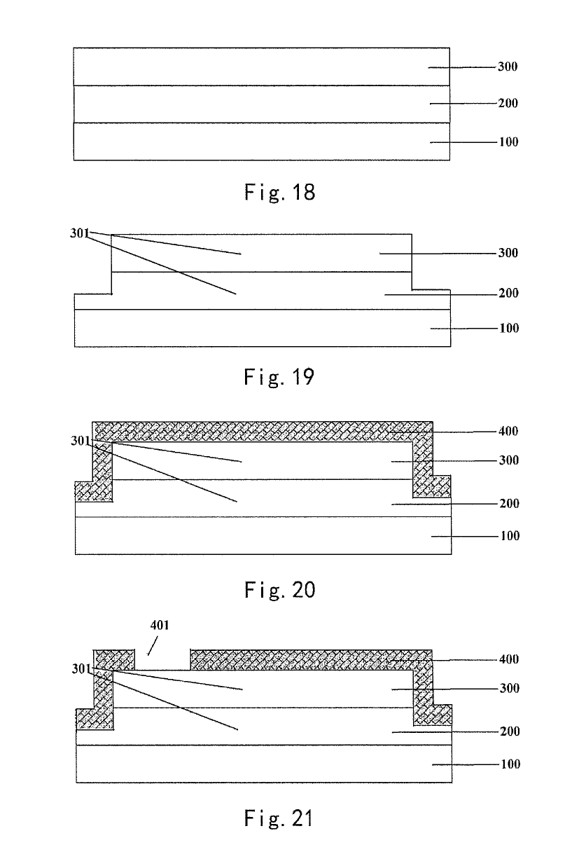

A second embodiment of the method of manufacturing a GaN-based Schottky diode rectifier is shown in FIGS. 18-28.

As shown in FIG. 18, a GaN intrinsic layer 200 with a thickness in a range of 50 nm˜10 μm is grown on a substrate 100. An AlGaN barrier layer 300 with a thickness in a range of 20 nm˜1 μm is grown on the GaN intrinsic layer 200. The substrate 100 may be made of GaN, sapphire, Si, diamond or SiC. The barrier layer 300 may be made of AlN, InN, InGaN or InAlN.

As shown in FIG. 19, a protruded mesa pattern 301 is formed from the AlGaN barrier layer 300 and the GaN intrinsic layer 200 by removing unwanted material from the AlGaN barrier layer 300 and the GaN intrinsic layer 200 by using lithographic technology and plasma dry etching technology. A GaN-based Schottky diode device may be manufactured on the mesa pattern 301, such that one device may be formed on one mesa. Since there is no two-dimension electron gas connecting the mesas, the mesas are electrically insulated or isolated from each other such that a plurality of GaN-based Schottky diode devices on the same wafer are electrically insulated or isolated from each other. The height of the mesa may be larger than or equal to the thickness of the AlGaN barrier layer 300.

As shown in FIG. 20, a first passivated dielectric layer 400 is deposited on the mesa 301 and the passivated dielectric layer 400 may be made of SiO₂, Si₃N₄, AlN, Al₂O₃, MgO, Sc₂O₃, TiO₂, HfO₂, BCB, ZrO₂, Ta₂O₅ or La₂O₃. The first passivated dielectric layer 400 may be deposited by sputtering or chemical vapor deposition (CVD) or epitaxial growth and may have a thickness in a range of 5 nm˜10 μm. Preferably, the passivated dielectric layer 400 may have a thickness of 20 nm.

As shown in FIG. 21, the first passivated dielectric layer 400 is formed with a pattern 401 by lithographic, plasma dry etching or wet etching technology. The pattern 401 may have a depth that is the same as the thickness of the passivated dielectric layer 400.

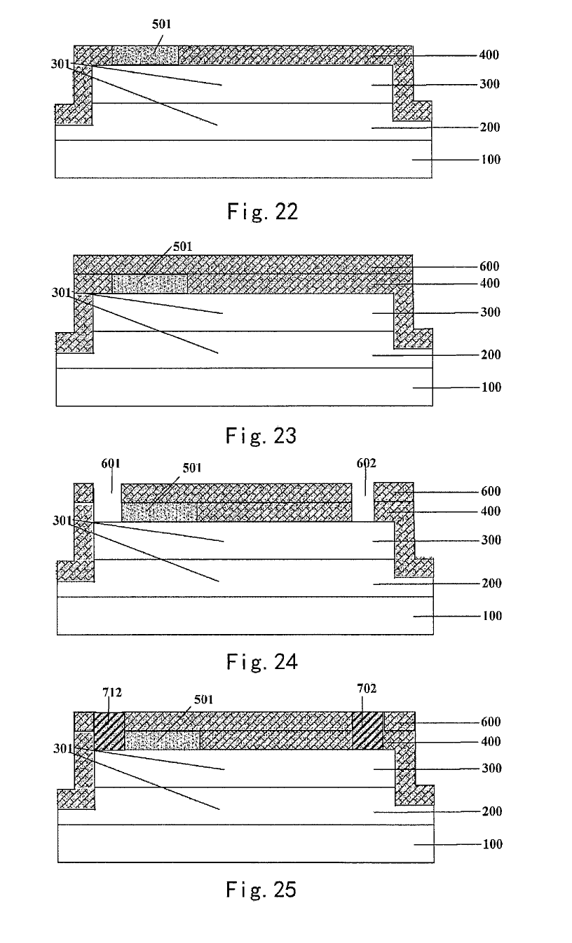

As shown in FIG. 22, a p-GaN layer 501 is selectively grown in the pattern 401, the p-GaN layer 501 may be grown by metal organic chemical vapor deposition (MOCVD), molecular-beam epitaxy (MBE) or atomic layer deposition. The selectively grown p-GaN layer 501 may have a thickness in a range of 20 nm˜1 μm. Preferably, the p-GaN layer 501 may have a thickness of 20 nm. The upper surface of the p-GaN layer 501 may do not exceed beyond that of the passivated dielectric layer 400 in grown direction or epitaxial direction. The p-GaN layer 501 may be made of GaN or AlGaN and may have a dopant concentration in a range of 10¹⁵˜10²¹ cm⁻³, preferably of 10²⁰ cm⁻³.

As shown in FIG. 23, a second passivated dielectric layer 600 is deposited on the first passivated dielectric layer 400. The second passivated dielectric layer 600 is made of SiO₂, Si₃N₄, AlN, Al₂O₃, MgO, Sc₂O₃, TiO₂, HfO₂, BCB, ZrO₂, Ta₂O₅ or La₂O₃. The second passivated dielectric layer 600 is deposited by sputtering or chemical vapor deposition (CVD) and may have a thickness in a range of 20 nm˜1 μm.

As shown in FIG. 24, the first passivated dielectric layer 400 and the second passivated dielectric layer 600 are formed with patterns 601 and 602 by lithographic, plasma dry etching or wet etching technology. The patterns 601 and 602 are required to have a depth that is the same as a sum of the thickness of the first passivated dielectric layer 400 and the second thickness of the passivated dielectric layer 600.

As shown in FIG. 25, metal electrodes 712 and 702 are respectively formed in the patterns 601 and 602 by lithographic, electron beam evaporation or sputtering technology. The metal electrodes 712 and 702 are respectively located at either side of the p-GaN layer 501, such that the metal electrode 702 is not in contact with the p-GaN layer 501 while the metal electrode 712 is in contact with the p-GaN layer 501. In this instance, the structure formed by this method may be more compact and may reduce size of a chip. The metal electrodes 712 and 702 may be made of Ti, Al, Ni, Mo, Pt, Pd, Au, W, TiW, TiN or any of combinations thereof. Ohmic contacts may be obtained between the metal electrodes 712 and 702 and the AlGaN barrier layer 300 by high temperature alloy annealing.

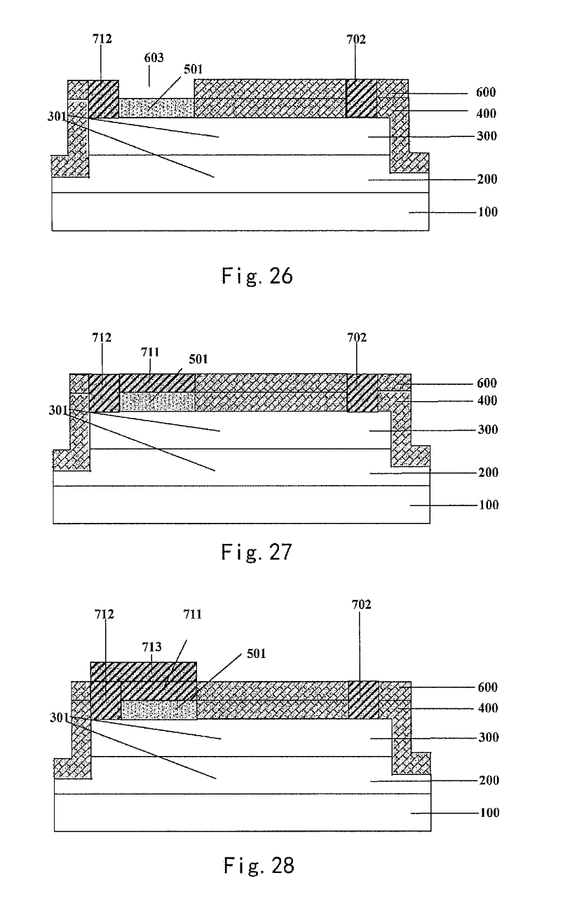

As shown in FIG. 26, a pattern 603 is formed in the second passivated dielectric layer 600 by lithographic, plasma dry etching or wet etching technology. The pattern 603 is required to have a depth that is large enough to fully expose the p-GaN layer 501.

As shown in FIG. 27, a metal electrode 711 is formed in the pattern 603 by lithographic, electron beam evaporation or sputtering technology. The metal electrode 711 may be made of Ti, Al, Ni, Mo, Pt, Pd, Au, W, TiW, TiN or any of combinations thereof. Ohmic contact may be formed between the metal electrode 711 and the p-GaN layer 501 by high temperature alloy annealing, or Schottky contact may be formed therebetween.

As shown in FIG. 28, a metal electrode 713 is formed on the second passivated dielectric layer 600 by electron beam evaporation or sputtering technology. The metal electrode 713 may be made of Ti, Al, Ni, Mo, Pt, Pd, Au, W, TiW, TiN or any of combinations thereof.

In the second embodiment, since the metal electrodes 712 and 711 abut to each other, a direct electrical connection may be achieved between the metal electrodes 712 and 711. Thus, as an alternative, the metal electrode 713 may be omitted to simplify the whole structure of the device.

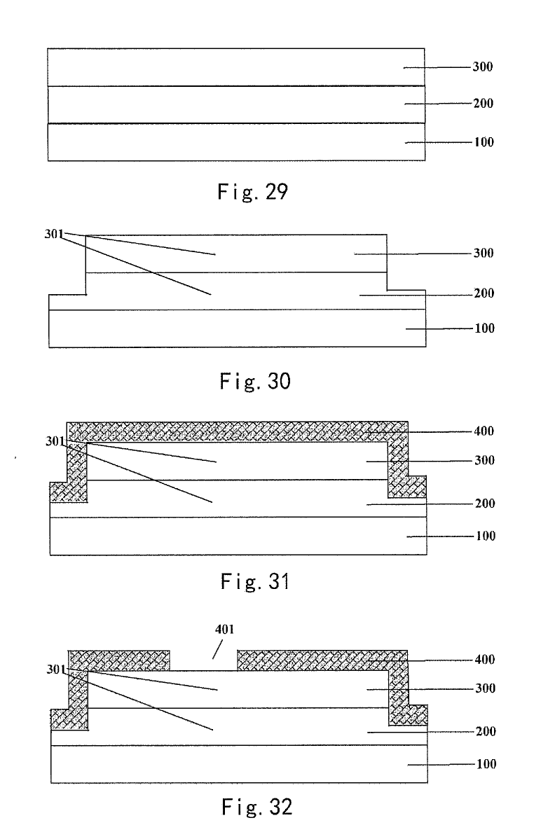

A third embodiment of the method of manufacturing a GaN-based Schottky diode rectifier is shown in FIGS. 29-37.

As shown in FIG. 29, a GaN intrinsic layer 200 with a thickness in a range of 50 nm˜10 μm is grown on a substrate 100. An AlGaN barrier layer 300 with a thickness in a range of 20 nm˜1 μm is grown on the GaN intrinsic layer 200. The substrate 100 may be made of GaN, sapphire, Si, diamond or SiC. The barrier layer 300 may be made of AlN, InN, InGaN or InAlN.

As shown in FIG. 30, a protruded mesa pattern 301 is formed from the AlGaN barrier layer 300 and the GaN intrinsic layer 200 by removing unwanted material from the AlGaN barrier layer 300 and the GaN intrinsic layer 200 by using lithographic technology and plasma dry etching technology. A GaN-based Schottky diode rectifier/device may be manufactured on the mesa pattern 301, such that one device may be formed on one mesa. Since there is no two-dimension electron gas connecting the mesas, the mesas are electrically insulated or isolated from each other such that a plurality of GaN-based Schottky diode devices in the same wafer are electrically insulated or isolated from each other. The height of the mesa may be larger than the thickness of the AlGaN barrier layer 300.

As shown in FIG. 31, a first passivated dielectric layer 400 is deposited on the mesa 301 and the passivated dielectric layer 400 may be made of SiO₂, Si₃N₄, AlN, Al₂O₃, MgO, Sc₂O₃, TiO₂, HfO₂, BCB, ZrO₂, Ta₂O₅ or La₂O₃. The first passivated dielectric layer 400 may be deposited by sputtering or chemical vapor deposition (CVD) or epitaxial growth and may have a thickness in a range of 5 nm˜10 μm. Preferably, the passivated dielectric layer 400 may have a thickness of 20 nm.

As shown in FIG. 32, a pattern 401 is formed in the first passivated dielectric layer 400 by lithographic, plasma dry etching or wet etching technology. The pattern 401 may have a depth that is the same as the thickness of the passivated dielectric layer 400.

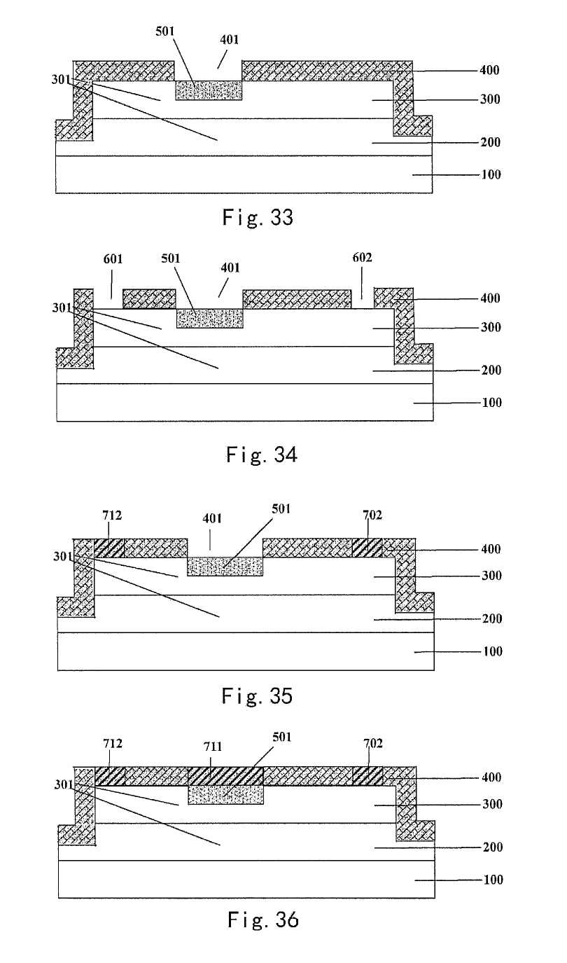

As shown in FIG. 33, p-type dopant is implanted into the AlGaN barrier layer 300 by an ion implantation such that a p-type doped region 501 is formed in the AlGaN barrier layer 300 and is activated by annealing. The implanted ion may be any of Mg, Si, C or a combination thereof. The implantation energy may be 30 keV and the implantation dose may be 10¹³ cm⁻². The p-type doped region 501 may have a dopant concentration of 10¹⁵˜10²¹ cm⁻³, and preferably 10²⁰ cm⁻³. The p-type doped region 501 may have a depth less than or equal to the thickness of the AlGaN barrier layer 300. Preferably, the depth of the p-type doped region 501 may be equal to half the thickness of the AlGaN barrier layer 300. This embodiment of the method does not involve secondary epitaxy by MOCVD and thus may reduce process cost.

As shown in FIG. 34, patterns 601 and 602 are formed in the passivated dielectric layer 400 by lithographic, plasma dry etching or wet etching technology.

As shown in FIG. 35, metal electrodes 712 and 702 are respectively formed in the patterns 601 and 602 by lithographic, electron beam evaporation or sputtering technology. The metal electrodes 712 and 702 are respectively located at either side of the p-GaN layer 501 and are not in contact with the p-GaN layer 501. The metal electrodes 712 and 702 may be made of Ti, Al, Ni, Mo, Pt, Pd, Au, W, TiW, TiN or any of combinations thereof. Ohmic contacts may be obtained between the metal electrodes 712 and 702 and the AlGaN barrier layer 300 by high temperature alloy annealing.

As shown in FIG. 36, a metal electrode 711 is formed in the pattern 401 by lithographic, electron beam evaporation or sputtering technology. The metal electrode 711 may be made of Ti, Al, Ni, Mo, Pt, Pd, Au, W, TiW, TiN or any of combinations thereof. Ohmic contact may be formed between the metal electrode 711 and the p-GaN layer 501 by high temperature alloy annealing, or Schottky contact may be formed therebetween.

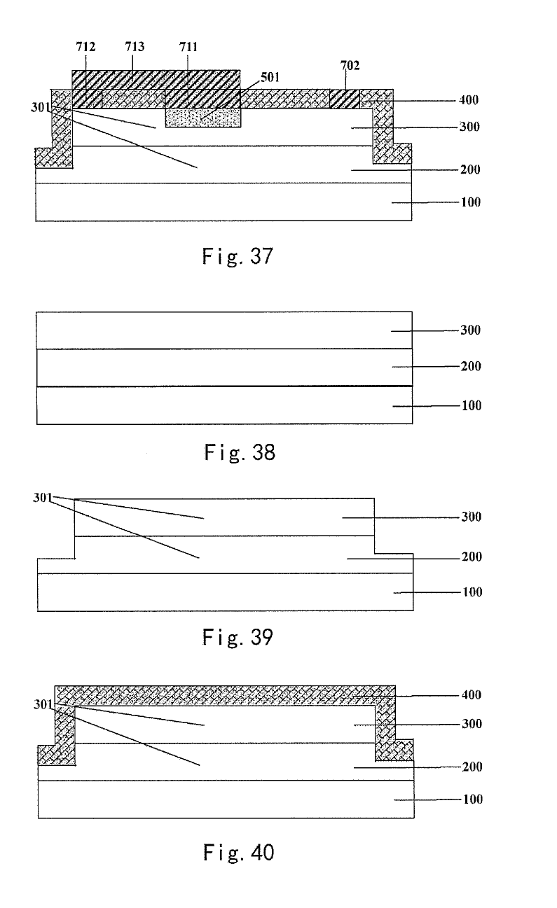

As shown in FIG. 37, a metal electrode 713 is formed on the second passivated dielectric layer 400 by electron beam evaporation or sputtering technology. The metal electrode 713 may be made of Ti, Al, Ni, Mo, Pt, Pd, Au, W, TiW, TiN or any of combinations thereof.

A fourth embodiment of the method of manufacturing a GaN-based Schottky diode rectifier is shown in FIGS. 38-46.

As shown in FIG. 38, a GaN intrinsic layer 200 with a thickness in a range of 50 nm˜10 μm is grown on a substrate 100. An AlGaN barrier layer 300 with a thickness in a range of 20 nm˜1 μm is grown on the GaN intrinsic layer 200. The substrate 100 may be made of GaN, sapphire, Si, diamond or SiC. The barrier layer 300 may be made of AlN, InN, InGaN or InAlN.

As shown in FIG. 39, a protruded mesa pattern 301 is formed from the AlGaN barrier layer 300 and the GaN intrinsic layer 200 by removing unwanted material from the AlGaN barrier layer 300 and the GaN intrinsic layer 200 by using lithographic technology and plasma dry etching technology. A GaN-based Schottky diode device may be manufactured on the mesa pattern 301, such that one device may be formed on one mesa. Since there is no two-dimension electron gas connecting the mesas, the mesas are electrically insulated or isolated from each other such that a plurality of GaN-based Schottky diode devices on the same wafer are electrically insulated or isolated from each other. The height of the mesa may be larger than or equal to the thickness of the AlGaN barrier layer 300.

As shown in FIG. 40, a first passivated dielectric layer 400 is deposited on the mesa 301 and the passivated dielectric layer 400 may be made of SiO₂, Si₃N₄, AlN, Al₂O₃, MgO, Sc₂O₃, TiO₂, HfO₂, BCB, ZrO₂, Ta₂O₅ or La₂O₃. The first passivated dielectric layer 400 may be deposited by sputtering or chemical vapor deposition (CVD) or epitaxial growth and may have a thickness in a range of 5 nm˜10 μm. Preferably, the passivated dielectric layer 400 may have a thickness of 20 nm.

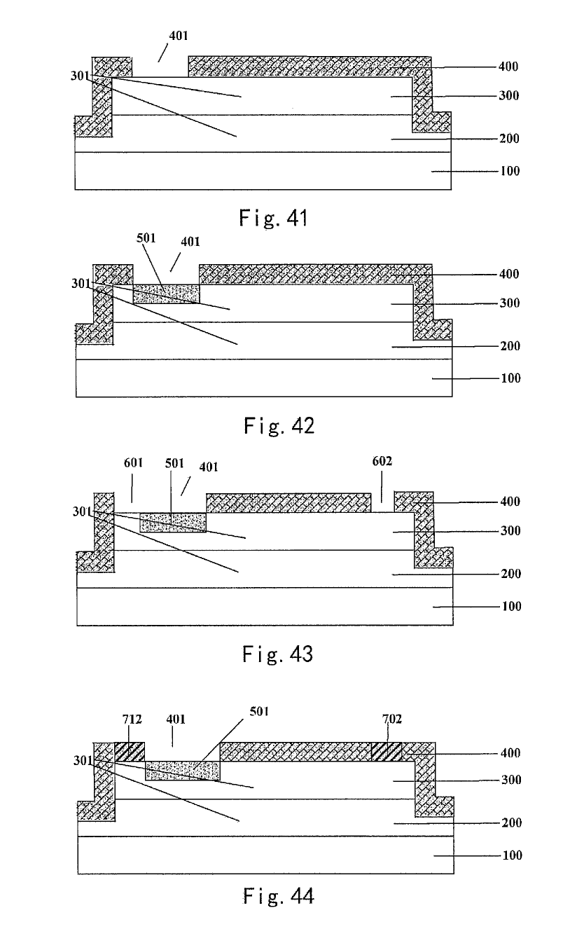

As shown in FIG. 41, a pattern 401 is formed in the first passivated dielectric layer 400 by lithographic, plasma dry etching or wet etching technology. The pattern 401 may have a depth that is the same as the thickness of the passivated dielectric layer 400.

As shown in FIG. 42, p-type dopant is implanted into the AlGaN barrier layer 300 by an ion implantation process such that a p-type doped region 501 is formed in the AlGaN barrier layer 300 and is activated by annealing. The implanted ion may be any of Mg, Si, C or a combination thereof. The implantation energy may be 30 keV and the implantation dose may be 10¹³ cm⁻². The p-type doped region 501 may have a dopant concentration of 10¹⁵˜10²¹ cm⁻³, and preferably 10²⁰ cm⁻³. The p-type doped region 501 may have a depth less than or equal to the thickness of the AlGaN barrier layer 300. Preferably, the depth of the p-type doped region 501 may be equal to halft the thickness of the AlGaN barrier layer 300.

As shown in FIG. 43, patterns 601 and 602 are formed in the passivated dielectric layer 400 by lithographic, plasma dry etching or wet etching technology.

As shown in FIG. 44, metal electrodes 712 and 702 are respectively formed in the patterns 601 and 602 by lithographic, electron beam evaporation or sputtering technology. The metal electrodes 712 and 702 are respectively located at either side of the p-GaN layer 501, such that the metal electrode 702 is not in contact with the p-GaN layer 501 and the metal electrode 712 is in contact with the p-GaN layer 501. The metal electrodes 712 and 702 may be made of Ti, Al, Ni, Mo, Pt, Pd, Au, W, TiW, TiN or any of combinations thereof. Ohmic contacts may be obtained between the metal electrodes 712 and 702 and the AlGaN barrier layer 300 by high temperature alloy annealing.

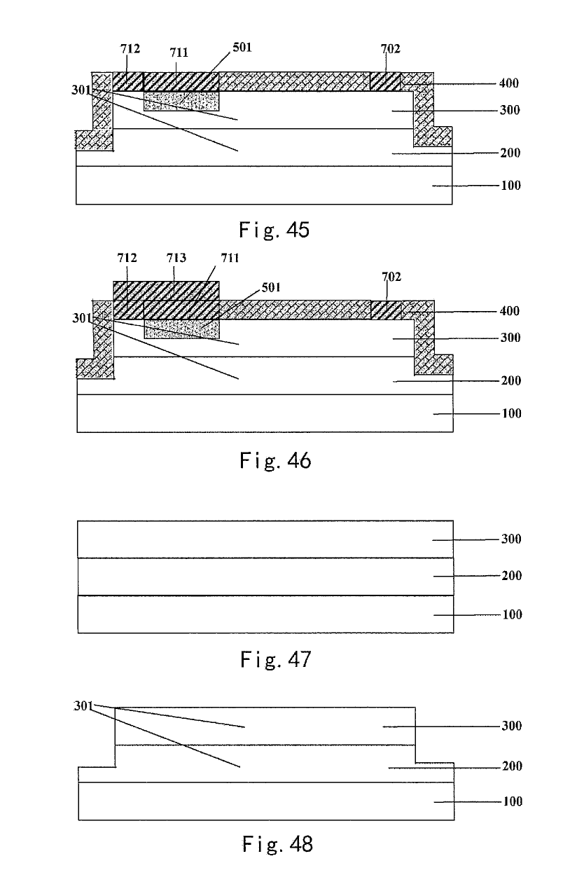

As shown in FIG. 45, a metal electrode 711 is formed in the pattern 401 by lithographic, electron beam evaporation or sputtering technology. The metal electrode 711 may be made of Ti, Al, Ni, Mo, Pt, Pd, Au, W, TiW, TiN or any of combinations thereof. Ohmic contact may be formed between the metal electrode 711 and the p-GaN layer 501 by high temperature alloy annealing, or Schottky contact may be formed therebetween.

As shown in FIG. 46, a metal electrode 713 is formed on the second passivated dielectric layer 400 by electron beam evaporation or sputtering technology. The metal electrode 713 may be made of Ti, Al, Ni, Mo, Pt, Pd, Au, W, TiW, TiN or any of combinations thereof.

In this fourth embodiment, as the metal electrodes 712 and 711 abut to each other, a direct electrical connection may be achieved between the metal electrodes 712 and 711. Thus, as an alternative, the metal electrode 713 may be omitted to simplify the whole structure of the device.

A fifth embodiment of the method of manufacturing a GaN-based Schottky diode rectifier is shown in FIGS. 47-56.

As shown in FIG. 47, a GaN intrinsic layer 200 with a thickness in a range of 50 nm˜10 μm is grown on a substrate 100. An AlGaN barrier layer 300 with a thickness in a range of 20 nm˜1 μm is grown on the GaN intrinsic layer 200. The substrate 100 may be made of GaN, sapphire, Si, diamond or SiC. The barrier layer 300 may be made of AlN, InN, InGaN or InAlN.

As shown in FIG. 48, a protruded mesa pattern 301 is formed from the AlGaN barrier layer 300 and the GaN intrinsic layer 200 by removing unwanted materials from the AlGaN barrier layer 300 and the GaN intrinsic layer 200 by using lithographic technology and plasma dry etching technology. A GaN-based Schottky diode device may be manufactured on the mesa pattern 301, such that one device may be formed on one mesa. Since there is no two-dimension electron gas connecting the mesas, the mesas are electrically insulated or isolated from each other such that a plurality of GaN-based Schottky diode devices on the same wafer are electrically insulated or isolated from each other. The height of the mesa may be larger than or equal to the thickness of the AlGaN barrier layer 300.

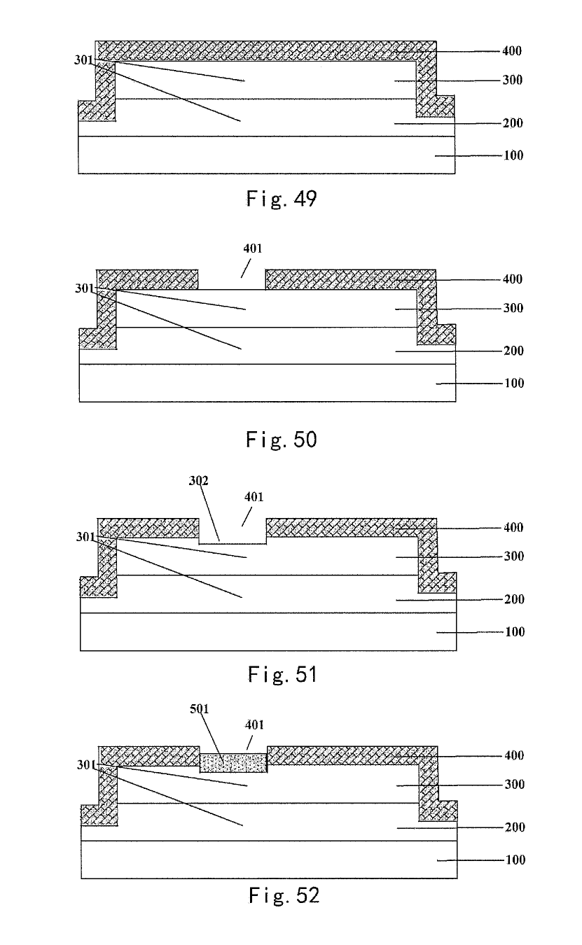

As shown in FIG. 49, a first passivated dielectric layer 400 is deposited on the mesa 301 and the passivated dielectric layer 400 may be made of SiO₂, Si₃N₄, AlN, Al₂O₃, MgO, Sc₂O₃, TiO₂, HfO₂, BCB, ZrO₂, Ta₂O₅ or La₂O₃. The first passivated dielectric layer 400 is deposited in manner by sputtering or chemical vapor deposition, or epitaxy growth. The passivated dielectric layer 400 may have a thickness of 5 nm˜10 μm. Preferably, the passivated dielectric layer 400 may have a thickness of 20 nm.

As shown in FIG. 50, a pattern 401 is formed in the first passivated dielectric layer 400 by lithographic, plasma dry etching or wet etching technology. The pattern 401 may have a depth that is the same as the thickness of the passivated dielectric layer 400.

As shown in FIG. 51, a pattern 302 is formed in the AlGaN barrier layer 300 by plasma dry etching or wet etching technology. The depth of the pattern 302 may be smaller than or equal to the thickness of the barrier layer 300. Preferably, the depth of the pattern 302 may be equal to half the thickness of the barrier layer 300.

As shown in FIG. 52, a p-GaN layer 501 is selectively re-grown in the pattern 302, the p-GaN layer 501 may be grown by MOCVD, molecular-beam epitaxy (MBE) or atomic layer deposition (ALD). The selectively grown p-GaN layer 501 may have a thickness in a range of 20 nm˜1 μm. Preferably, the p-GaN layer 501 may have a thickness of 20 nm. Upper surface of the p-GaN layer 501 does not exceed beyond that of the passivated dielectric layer 400 in an epitaxy direction or grown direction. The p-GaN layer 501 may be made of GaN or AlGaN and may have a dopant concentration in a range of 10¹⁵˜10²¹ cm⁻³, preferably of 10²⁰ cm⁻³. The upper surface of the p-GaN layer 501 exceeds beyond or is substantially flush with that of the barrier layer 300 in the epitaxy direction, and does not exceed beyond that of the passivated dielectric layer 400. Regrowing the p-GaN layer may reduce dopant concentration of the p-GaN layer 501 and thus render reduced leakage current.

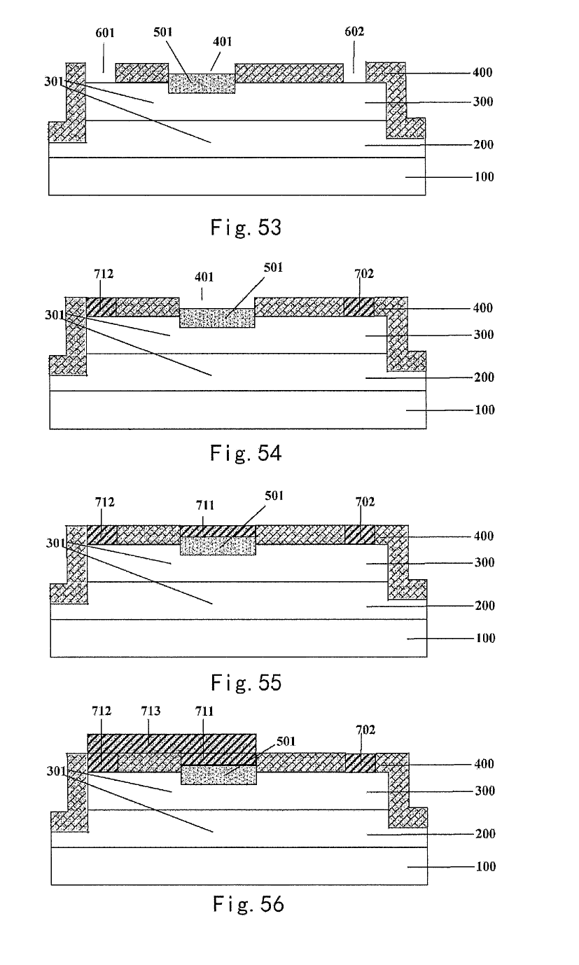

As shown in FIG. 53, patterns 601 and 602 are formed in the passivation dielectric layer 400 by lithographic, plasma dry etching or wet etching technology.

As shown in FIG. 54, metal electrodes 712 and 702 are respectively formed in the patterns 601 and 602 by lithographic, electron beam evaporation or sputtering technology. The metal electrodes 712 and 702 are respectively located at either side of the p-GaN layer 501 and are not in contact with the p-GaN layer 501. The metal electrodes 712 and 702 may be made of Ti, Al, Ni, Mo, Pt, Pd, Au, W, TiW, TiN or any of combinations thereof. Ohmic contacts may be obtained between the metal electrodes 712 and 702 and the AlGaN barrier layer 300 by high temperature alloy annealing.

As shown in FIG. 55, a metal electrode 711 is formed in the pattern 401 by lithographic, electron beam evaporation or sputtering technology. The metal electrode 711 may be made of Ti, Al, Ni, Mo, Pt, Pd, Au, W, TiW, TiN or any of combinations thereof. Schottky contact may be formed between the metal electrode 711 and the p-GaN layer 501, or ohmic contact may be formed therebetween by high temperature alloy annealing.

As shown in FIG. 56, a metal electrode 713 is formed on the second passivated dielectric layer 400 by electron beam evaporation or sputtering technology. The metal electrode 713 may be made of Ti, Al, Ni, Mo, Pt, Pd, Au, W, TiW, TiN or any of combinations thereof.

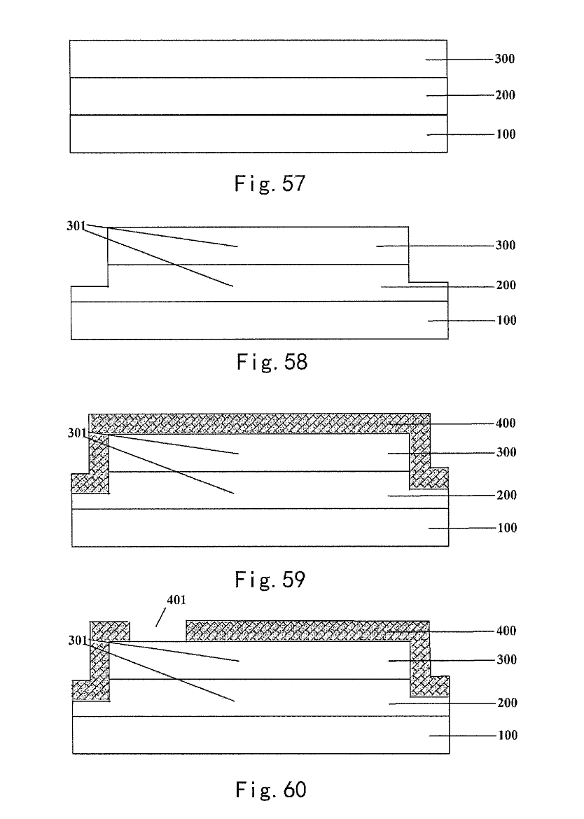

A sixth embodiment of the method of manufacturing a GaN-based Schottky diode rectifier is shown in FIGS. 57-66.

As shown in FIG. 57, a GaN intrinsic layer 200 with a thickness in a range of 50 nm˜10 μm is grown on a substrate 100. An AlGaN barrier layer 300 with a thickness in a range of 20 nm˜1 μm is grown on the GaN intrinsic layer 200. The substrate 100 may be made of GaN, sapphire, Si, diamond or SiC. The barrier layer 300 may be made of AlN, InN, InGaN or InAlN.

As shown in FIG. 58, a protruded mesa pattern 301 is formed from the AlGaN barrier layer 300 and the GaN intrinsic layer 200 by removing unwanted materials from the AlGaN barrier layer 300 and the GaN intrinsic layer 200 by using lithographic technology and plasma dry etching technology. A GaN-based Schottky diode device may be manufactured on the mesa pattern 301, such that one device may be formed on one mesa. Since there is no two-dimension electron gas connecting the mesas, the mesas are electrically insulated or isolated from each other such that a plurality of GaN-based Schottky diode devices on the same wafer are electrically insulated or isolated from each other. The height of the mesa may be larger than or equal to the thickness of the AlGaN barrier layer 300.

As shown in FIG. 59, a first passivated dielectric layer 400 is deposited on the mesa 301 and the passivated dielectric layer 400 may be made of SiO₂, Si₃N₄, AlN, Al₂O₃, MgO, Sc₂O₃, TiO₂, HfO₂, BCB, ZrO₂, Ta₂O₅ or La₂O₃. The first passivated dielectric layer 400 may be deposited by sputtering or chemical vapor deposition (CVD) or epitaxial growth and may have a thickness in a range of 5 nm˜10 μm. Preferably, the passivated dielectric layer 400 may have a thickness of 20.

As shown in FIG. 60, a pattern 401 is formed in the first passivated dielectric layer 400 by lithographic, plasma dry etching or wet etching technology. The pattern 401 may have a depth that is the same as the thickness of the passivated dielectric layer 400.

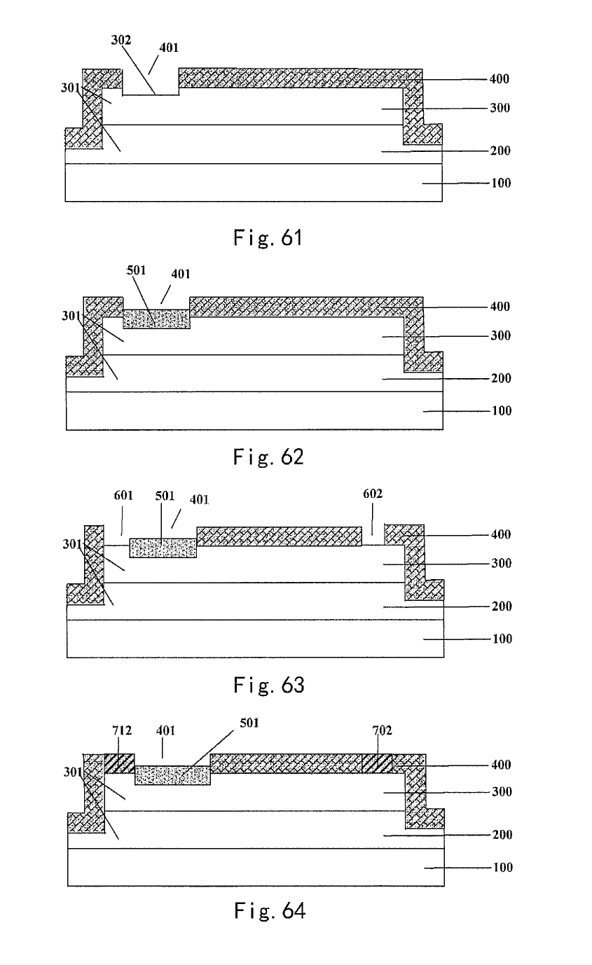

As shown in FIG. 61, a pattern 302 is formed in the AlGaN barrier layer 300 is formed with by plasma dry etching or wet etching technology. The pattern 302 has a depth smaller than or equal to the thickness of the barrier layer 300. Preferably, the depth of the pattern 302 is half the thickness of the barrier layer 300.

As shown in FIG. 62, a p-GaN layer 501 is selectively re-grown in the pattern 302, the p-GaN layer 501 may be grown or deposited by MOCVD, molecular-beam epitaxy (MBE) or atomic layer deposition (ALD). The selectively grown p-GaN layer 501 may have a thickness in a range of 20 nm˜1 μm. Preferably, the p-GaN layer 501 may have a thickness of 20 nm. The upper surface of the p-GaN layer 501 does not exceed beyond that of the passivated dielectric layer 400 in a grown direction or epitaxial direction. The p-GaN layer 501 may be made of GaN or AlGaN and may have a dopant concentration in a range of 10¹⁵˜10²¹ cm⁻³, preferably of 10²⁰ cm⁻³.

As shown in FIG. 63, patterns 601 and 602 are formed in the passivated dielectric layer 400 by lithographic, plasma dry etching or wet etching technology.

As shown in FIG. 64, metal electrodes 712 and 702 are respectively formed in the patterns 601 and 602 by lithographic, electron beam evaporation or sputtering technology. The metal electrodes 712 and 702 are respectively located at either side of the p-GaN layer 501, such that the metal electrode 702 is not in contact with the p-GaN layer 501 while the metal electrode 712 is in contact with the p-GaN layer 501. The metal electrodes 712 and 702 may be made of Ti, Al, Ni, Mo, Pt, Pd, Au, W, TiW, TiN or any of combinations thereof. Ohmic contacts may be obtained between the metal electrodes 712 and 702 and the AlGaN barrier layer 300 by high temperature alloy annealing.

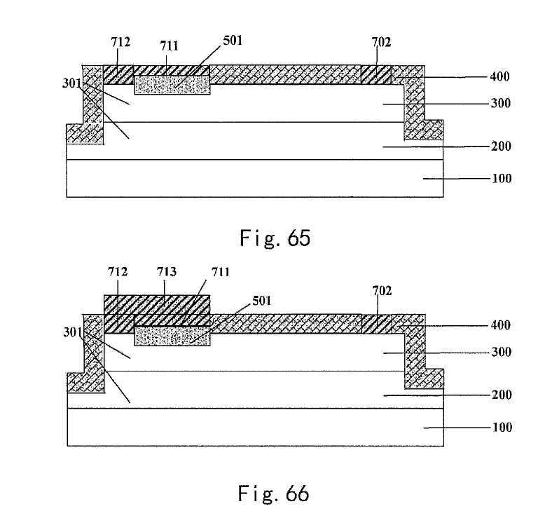

As shown in FIG. 65, a metal electrode 711 is formed in the pattern 401 by lithographic, electron beam evaporation or sputtering technology. The metal electrode 711 may be made of Ti, Al, Ni, Mo, Pt, Pd, Au, W, TiW, TiN or any of combinations thereof. Schottky contact may be formed between the metal electrode 711 and the p-GaN layer 501, or ohmic contact may be formed therebetween by high temperature alloy annealing.

As shown in FIG. 66, a metal electrode 713 is formed on the second passivated dielectric layer 400 by electron beam evaporation or sputtering technology. The metal electrode 713 may be made of Ti, Al, Ni, Mo, Pt, Pd, Au, W, TiW, TiN or any of combinations thereof.

In this sixth embodiment, as the metal electrodes 712 and 711 abut to each other, a direct electrical connection may be achieved between them. Thus, as an alternative, the metal electrode 713 may be omitted to simplify the whole structure of the device.

The above specific embodiments are intended to explain the objects, solutions and advantages of the present application in detail. It should be noted that the above embodiments are provided only by way of examples, other than limiting the present disclosure. All changes, alternatives or modifications which are made within the principles and spirit of the present application should fall within the scopes of the present disclosure.

What is claimed is:

1. A GaN-based Schottky diode rectifier, comprising:
a substrate, on which a GaN intrinsic layer and a barrier layer are grown in turn;
a p-type two-dimension electron gas depletion layer located on an upper surface of the barrier layer to cover a part or whole of the upper surface of the barrier layer, or partially or fully formed in the upper surface of the barrier layer;
a cathode electrode located at a position on the upper surface of the barrier layer which is different from the position where the p-type two-dimension electron gas depletion layer is located; and
an anode electrode including a first part and a second part that are electrically connected to each other, wherein the first part of the anode electrode is located on an upper surface of the p-type two-dimension electron gas depletion layer and the second part of the anode electrode is in contact with a part of the upper surface of the barrier layer that is not covered by the p-type two-dimension electron gas depletion layer, and the second part and the cathode electrode are located at either side of the p-type two-dimension electron gas depletion layer.

2. The GaN-based Schottky diode rectifier according to claim 1, wherein the upper surface of the barrier layer is covered by a passivated dielectric layer the passivated dielectric layer covering rest parts of the upper surface of the barrier layer that is not covered by other layers.

3. The GaN-based Schottky diode rectifier according to claim 2, wherein the second part and the first part abut to each other or are separated from each other by the passivated dielectric layer.

4. The GaN-based Schottky diode rectifier according to claim 1, wherein the barrier layer is made of AlN, InN, AlGaN, InGaN or InAlN.

5. The GaN-based Schottky diode rectifier according to claim 1, wherein the p-type two-dimension electron gas depletion layer is made of GaN, AlN, InN, AlGaN, InGaN or InAlN.

6. The GaN-based Schottky diode rectifier according to claim 1, wherein the p-type two-dimension electron gas depletion layer has a dopant concentration of 10¹⁵˜10²¹ cm⁻³, preferably 10²⁰ cm⁻³.

7. The GaN-based Schottky diode rectifier according to claim 1, wherein ohmic contact is formed between the second part of the anode electrode and the cathode electrode and the barrier layer, respectively; and Schottky contact or ohmic contact is formed between the first part of the anode electrode and the p-type two-dimension electron gas depletion layer.

8. The GaN-based Schottky diode rectifier according to claim 3, wherein the anode electrode further comprises a third part, via which the second part and the first part separated from each other are electrically connected to each other.

9. A method of manufacturing a GaN-based Schottky diode rectifier, the method comprising steps of:
forming a GaN intrinsic layer on the substrate and forming a barrier layer on the GaN intrinsic layer;
defining a region for forming a p-type two-dimension electron gas depletion layer on or in an upper surface of the barrier layer;
forming the p-type two-dimension electron gas depletion layer in the region;
forming a cathode electrode at a position on the upper surface of the barrier layer which is different from the position where the p-type two-dimension electron gas depletion layer is formed;
forming an anode electrode including a first part and a second part that are electrically connected to each other, wherein the first part of the anode electrode is located on an upper surface of the p-type two-dimension electron gas depletion layer and the second part of the anode electrode is formed at a position of the upper surface of the barrier layer that is different from the position where the p-type two-dimension electron gas depletion layer is formed, and the second part and the cathode electrode are located at either side of the p-type two-dimension electron gas depletion layer.

10. The method of manufacturing a GaN-based Schottky diode rectifier according to claim 9, wherein the upper surface of the barrier layer is covered by a passivated dielectric layer, the passivated dielectric layer covering rest parts of the upper surface of the barrier layer which are not covered by other layers.

11. The method of manufacturing a GaN-based Schottky diode rectifier according to claim 9, wherein the second part and the first part abut to each other or are separated from each other by the passivated dielectric layer.

12. The method of manufacturing a GaN-based Schottky diode rectifier according to claim 9, wherein the barrier layer is made of AlN, InN, AlGaN, InGaN or InAlN.

13. The method of manufacturing a GaN-based Schottky diode rectifier according to claim 9, wherein the p-type two-dimension electron gas depletion layer is made of GaN, AlN, InN, AlGaN, InGaN or InAlN.

14. The method of manufacturing a GaN-based Schottky diode rectifier according to claim 9, wherein a depth of the region for forming the two-dimension electron gas depletion layer is defined to be smaller than the thickness of the barrier layer.

15. The method of manufacturing a GaN-based Schottky diode rectifier according to claim 9, wherein a depth of the region for forming the two-dimension electron gas depletion layer is defined to be half the thickness of the barrier layer.

16. The method of manufacturing a GaN-based Schottky diode rectifier according to claim 9, wherein the p-type two-dimension electron gas depletion layer has a dopant concentration of 10¹⁵˜10²¹ cm⁻³, preferably 10²⁰ cm⁻³.

17. The method of manufacturing a GaN-based Schottky diode rectifier according to claim 9, wherein the p-type two-dimension electron gas depletion layer is formed in an upper portion of the barrier layer by ion implantation process.

18. The method of manufacturing a GaN-based Schottky diode rectifier according to claim 9, wherein ohmic contact is formed between the second part of the anode electrode and the cathode electrode and the barrier layer respectively; and Schottky contact or ohmic contact is formed between the first part of the anode electrode and the p-type two-dimension electron gas depletion layer.

19. The method of manufacturing a GaN-based Schottky diode rectifier according to claim 9, further comprising a step of forming a mesa on the same substrate by ion implantation or etching so as to be isolated from other Schottky diode rectifier.

20. The method of manufacturing a GaN-based Schottky diode rectifier according to claim 9, wherein the step of defining a region for forming a p-type two-dimension electron gas depletion layer includes patterning the dielectric layer.

21. The method of manufacturing a GaN-based Schottky diode rectifier according to claim 9, wherein the anode electrode further includes a third part, via which the second part and the first part separated from each other are electrically connected to each other.
